(19) United States
(12) Patent Application Publication
(10) Pub. No.: US 2025/0293475 A1
(43) Pub. Date: Sep. 18, 2025

(54) AUTOMATIC CONNECTING SYSTEM FOR BSA INSPECTION

(71) Applicant: HYUNDAI MOBIS CO., LTD., Seoul (KR)

(72) Inventors: Jae In KIM, Yongin-si (KR); Ki Nyeon KIM, Yongin-si (KR); Soon Jong CHO, Yongin-si (KR); Jae Mu EOM, Yongin-si (KR); Hyun Wook JIN, Yongin-si (KR); Kang Sik SHIN, Yongin-si (KR); Hyo In SEO, Yongin-si (KR); Sae Yong JEON, Yongin-si (KR); Jong Ha KIM, Yongin-si (KR); Seong Jin KIM, Yongin-si (KR); Chan Hoe HEO, Yongin-si (KR)

(73) Assignee: HYUNDAI MOBIS CO., LTD., Seoul (KR)

(21) Appl. No.: 18/938,156

(22) Filed: Nov. 5, 2024

(30) Foreign Application Priority Data
Mar. 14, 2024 (KR) 10-2024-0035808

(51) Int. Cl. H01R 43/26; G06T 7/70; H01M 10/42

(52) U.S. Cl. CPC H01R 43/26; G06T 7/70; H01M 10/4285

(57) ABSTRACT

An automatic connecting system for a battery system assembly (BSA) inspection, including a vision unit configured to recognize a plurality of plugs provided in a battery system assembly, a connector connecting unit configured to grip connectors, the connectors respectively matching the plurality of plugs among the connectors, move the gripped connectors to positions of those plugs, and then connect the connectors to the plugs, one or more processors configured to execute instructions, and a memory storing the instructions, an execution of the instructions configures the one or more processors to receive information about the plurality of plugs recognized by the vision unit and control the connector connecting unit to operate.

### CROSS REFERENCE TO RELATED APPLICATION

The present application claims the benefit under 35 USC § 119(a) of Korean Patent Application No. 10-2024-0035808, filed on Mar. 14, 2024, in the Korean Intellectual Property Office, the entire disclosure of which is incorporated herein by reference for all purposes.

### BACKGROUND

### 1. Field of the Invention

The disclosure relates to a connector automatic connecting system for a battery system assembly (BSA) inspection.

### 2. Description of the Related Art

In general, a battery system assembly (BSA) is subjected to defect inspection when its manufacturing process is completed, and then shipped as an end product. Such a defect inspection is carried out in the state that connectors of an inspection apparatus are connected to plugs provided in the battery system assembly.

A conventional method of connecting the connectors to the plugs has been carried out in such a manner that a worker manually connects the connectors to the plugs. However, the conventional method has problems, such as missing inspection portions, increasing fatigue due to long-time manual work, and inspection time delay, as the number of connection portions increases.

Further, difficulties in identifying the shapes of the connectors in the case of the manual connection cause problems of poor connection and damage to the connector due to the poor connection. Therefore, there is a need to improve the problems.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided an automatic connecting system for a battery system assembly (BSA) inspection including a vision unit configured to recognize a plurality of plugs provided in a battery system assembly, a connector connecting unit configured to grip connectors, the connectors respectively matching the plurality of plugs among the connectors, move the gripped connectors to positions of those plugs, and then connect the connectors to the plugs, one or more processors configured to execute instructions, and a memory storing the instructions, an execution of the instructions configures the one or more processors to receive information about the plurality of plugs recognized by the vision unit and control the connector connecting unit to operate.

The connector connecting unit may include a first robot, the first robot including a first gripper configured to grip the connector and a second robot, the second robot including a second gripper configured to grip the connector, a first degree of freedom of the first robot being different from a second degree of freedom of the second robot.

The first robot may be configured to implement 6 degrees of freedom motion and the second robot may be configured to implement 3 degrees of freedom motion.

The first robot may include a 6-axis multi-joint robot and the second robot may include an orthogonal robot.

The first gripper and the second gripper each may include one or more of a finger type that pressurizes at least two points of the connector, an adsorption type that adsorbs the connector, and a magnetic type that attaches the connector thereto with magnetism.

The vision unit may include a camera, and the vision unit may be configured to face lateral and top surfaces of the battery system assembly to recognize the plurality of plugs.

The vision unit may further include a lighting unit configured to provide light.

The memory may include plug data about the plurality of plugs and connector data about the connectors matching the plurality of plugs and the one or more processors are further configured to receive information about the plurality of plugs recognized by the vision unit and compare the received information with the plug data and the connector data.

The automatic connecting system may include a frame unit in which the vision unit and the connector connecting unit are installed.

The frame unit may include a jig on which the battery system assembly is placed and a guide rail configured to guide the jig to move in a sliding motion.

### BRIEF DESCRIPTION OF THE DRAWINGS

FIG. 1 is a view schematically illustrating a connector automatic connecting system for a battery system assembly (BSA) inspection according to an embodiment of the disclosure.

FIG. 2 is a view schematically illustrating a battery system assembly.

FIG. 3 is a view schematically illustrating a vision unit.

FIG. 4 is a view schematically illustrating a connector connecting unit.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Advantages and features of the present disclosure and methods of achieving the advantages and features will be clear with reference to embodiments described in detail below together with the accompanying drawings. However, the present disclosure is not limited to the embodiments disclosed herein but will be implemented in various forms. The embodiments of the present disclosure are provided so that the present disclosure is completely disclosed, and a person with ordinary skill in the art can fully understand the scope of the present disclosure. The present disclosure will be defined only by the scope of the appended claims. Meanwhile, the terms used in the present specification are for explaining the embodiments, not for limiting the present disclosure.

Terms, such as first, second, A, B, (a), (b) or the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

In a description of the embodiment, in a case in which any one element is described as being formed on or under another element, such a description includes both a case in which the two elements are formed in direct contact with each other and a case in which the two elements are in indirect contact with each other with one or more other elements interposed between the two elements. In addition, when one element is described as being formed on or under another element, such a description may include a case in which the one element is formed at an upper side or a lower side with respect to another element.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

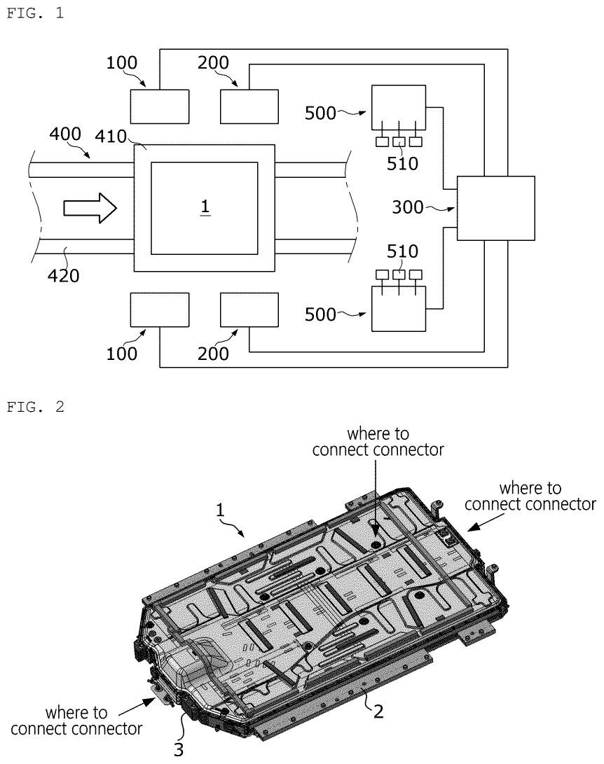

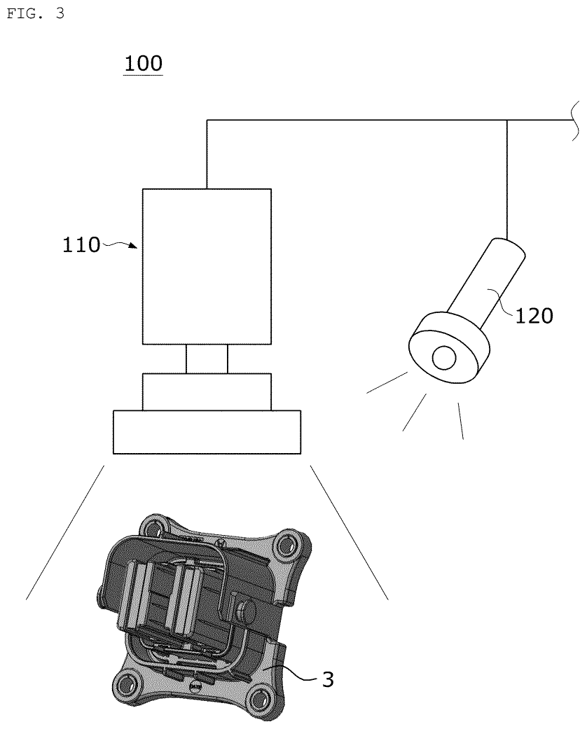

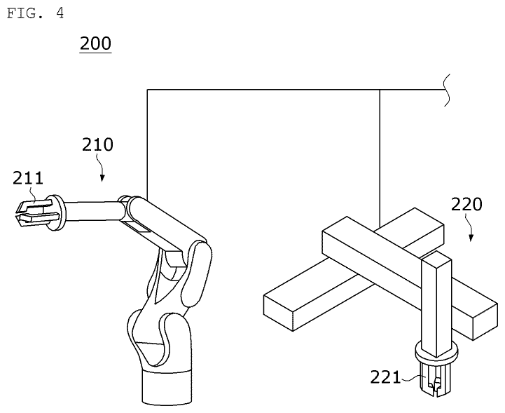

FIG. 1 is a view schematically illustrating a connector automatic connecting system for a battery system assembly (BSA) inspection according to an embodiment of the disclosure, FIG. 2 is a view schematically illustrating a battery system assembly, FIG. 3 is a view schematically illustrating a vision unit, and FIG. 4 is a view schematically illustrating a connector connecting unit.

As shown therein, a connector automatic connecting system for BSA inspection according to an embodiment of the disclosure may include a vision unit 100, a connector connecting unit 200, and a control device 300. Further, the connector automatic connecting system may further include a frame unit 400 in which the vision unit 100 and the connector connecting unit 200 are installed.

The control device 300 may be implemented as an electronic control unit (ECU), a central processing unit (CPU), a processor, or a system on chip (SoC), and may control a plurality of hardware or software components by driving an operating system or an application and perform various data processing and operations. The control device 300 may be configured to execute at least one instruction stored in a memory and store data, that is, a result of the execution, in the memory.

The frame unit 400 may form a frame structure for installing the vision unit 100 and the connector connecting unit 200.

The frame unit 400 may include a jig 410 on which the battery system assembly 1 is placed, and a guide rail 420 that guides the jig 410 to move in a sliding manner. The jig 410 may be connected to an actuator (not shown) and configured to slide along the guide rail 420. The battery system assembly 1 may be placed on the jig 410 and transported to a set position along the guide rail 420.

The battery system assembly 1 may include various plugs 3. For example, a lower casing 2 may be provided with a high voltage plug, an integrated charging control unit (ICCU) plug, a battery management system (BMS) plug, a power relay assembly (PRA) plug, etc. According to an embodiment, the plugs 3 may be provided on the lateral surface, top surface, etc. of the lower casing 2.

Connectors 510 of an inspection apparatus 500 may be connected to the plugs 3. In the state that the connectors 510 are connected to a plurality of plugs 3, the inspection apparatus 500 may perform inspections of the battery system assembly 1. For example, a plug defect/damage inspection, an insulation resistance inspection, a charge/discharge inspection, an airtightness inspection, an end-of-line (EOL) inspection, etc. may be carried out.

The vision unit 100 may be configured to recognize the plurality of plugs 3 provided in the battery system assembly 1, and the connector connecting unit 200 may be configured to connect the connector 510 to the plug 3. In addition, the vision unit 100 and the connector connecting unit 200 may be connected to the control device 300.

The vision unit 100 may include a camera 110. Further, the vision unit 100 may additionally include a lighting unit 120 that provides light.

The vision unit 100 may be installed to have a structure that faces the lateral and top surfaces of the battery system assembly 1 so as to recognize the plugs 3 of the battery system assembly 1. Information obtained through the vision unit 100 may be transmitted to the control device 300.

The connector connecting unit 200 may be configured to grip and connect a plurality of connectors 510 of the inspection apparatus 500 to the plugs 3. According to an embodiment, the connector connecting unit 200 may include a first robot 210 and a second robot 220 to grip the connectors 510.

The first robot 210 and the second robot 220 grip the connectors 510 respectively matching the plurality of plugs 3 among the connectors 510 of the inspection apparatus 500, move the gripped connectors 510 to the positions of those plugs 3, and then connect the connectors 510 to the plugs 3. Such operations of the first robot 210 and the second robot 220 may be performed under control of the control device 300.

According to an embodiment, the first robot 210 and the second robot 220 may be different in degrees of freedom from each other. For example, the first robot 210 may be configured to implement 6 degrees of freedom motion, and the second robot 220 may be configured to implement 3 degrees of freedom motion. In other words, the first robot 210 may include a 6-axis multi-joint robot, and the second robot 220 may include an orthogonal robot. Therefore, when it is difficult for the second robot 220 to connect the connector 510 to the plug 3 as the position of the plug 3 is inaccessible to the second robot 220, the first robot 210 may be configured to connect the connector 510 to the plug 3.

The first robot 210 may include a first gripper 211 to grip the connector 510, and the second robot 220 may include a second gripper 221 to grip the connector 510.

The first gripper 211 and the second gripper 221 may be implemented by any one of a finger type that pressurizes at least two points of the connector 510, an adsorption type that adsorbs the connector 510, and a magnetic type that attaches the connector 510 thereto with magnetism. The types of the first gripper 211 and the second gripper 221 may be varied depending on the shapes of the connector 510 and the kinds of inspection.

After connecting the connectors 510 to the matching plugs 3, the first robot 210 and the second robot 220 may maintain or release the grips on the connectors 510 according to the plug types. For example, the grip on the connector 510 is maintained after connecting the connector 510 to the high voltage plug, but the grip on the connector 510 may be released after connecting the connector 510 to the ICCU plug, the BMS plug, or the PRA plug.

The control device 300 may receive information about the plurality of plugs 3 recognized by the vision unit 100 and control the operation of the connector connecting unit 200.

The control device 300 may register and store plug data about the plurality of plugs 3 for each battery system assembly 1, and connector data about the plurality of connectors 510 of the inspection apparatus 500 matching the plurality of plugs 3.

According to an embodiment, the plug data may include the specifications (e.g., shapes) and locations of the plugs in the battery system assembly 1 according to the vehicle models. Further, the connector data may include the types and locations of the connectors 510 matching the specifications of the plugs 3. Such data may be registered in advance as classified according to the vehicle models.

The control device 300 compares the information received from the vision unit 100 with the registered data to determine whether the received data and the registered data are the same. When the registered data and the received information are not the same, a worker may be notified of error occurrence through a warning alarm or the like, and requested to perform reconfirmation. On the other hand, when the data and the information are the same, the connector connecting unit 200 may be controlled to operate.

Below, the operations of the connector automatic connecting system with this configuration for the BSA inspection will be described.

First, the plug data about the battery system assembly 1 for each vehicle model and the connector data about the connectors 510 of the inspection apparatus 500 matching the plurality of plugs are registered and stored in the control device 300.

When the battery system assembly 1 to be subjected to the inspection is placed on the jig 410, the information about the battery system assembly 1 is transmitted to the control device 300. Therefore, the control device 300 may recognize which vehicle model the battery system assembly 1 is installed in. The information of the battery system assembly 1 may be selected by a worker through an input means, or may be transmitted automatically through scanning.

When the battery system assembly 1 is placed on the jig 410 and transported to a set position along the guide rail 420 of the frame unit 400, the vision unit 100 transmits the information, which is obtained by recognizing the plurality of plugs 3 provided in the battery system assembly 1, to the control device 300.

The control device 300 compares the information received from the vision unit 100 with the registered plug data about the battery system assembly 1 of the corresponding vehicle model to determines whether the received information and the registered plug data are the same. For example, the control device 300 compares the information about the specifications and locations of the plug 3 with the registered plug data.

When the data and the information are not the same, the worker is informed of the error occurrence through a warning alarm, etc., and requested to perform reconfirmation. On the other hand, when the data and the information are the same, the connector connecting unit 200 is controlled to operate.

The connector connecting unit 200 grips the connectors 510 matching the plurality of plugs 3 among the connectors 510 of the inspection apparatus 500 based on a control signal of the control device 300. The connector connecting unit 200 controls the gripped connectors 510 to be moved to the positions of the plugs 3 and then connected to the plug 3. In this case, the connector connecting unit 200 may maintain or release the grip on the connector 510 according to the types of plug 3. For example, the grip on the connector 510 is maintained after connecting the connector 510 to the high voltage plug, but the grip on the connector 510 may be released to return the connector 510 to its original position after connecting the connector 510 to the ICCU plug, the BMS plug, or the PRA plug.

When the connectors 510 are connected to the plugs 3 of the battery system assembly 1 as above, the inspection apparatus 500 performs the inspections of the battery system assembly 1. For example, a plug defect/damage inspection, an insulation resistance inspection, a charge/discharge inspection, an airtightness inspection, an EOL inspection, etc. may be carried out.

When it is identified that the battery system assembly 1 has passed the inspection, the battery system assembly 1 may be transferred to the next process for product shipment.

As described above, according to an embodiment of the disclosure, the connectors 510 of the inspection apparatus 500 are automatically connected to the plugs 3 of the battery system assembly 1 when the inspections of the battery system assembly 1 are performed, thereby having effects on improving inspection quality and preventing casualties in the event of an unexplained fire occurring during the inspections of the battery system assembly 1.

Further, work time is shortened and work efficiency and production efficiency are enhanced because there are no problems, such as time delay, poor connection, and missing inspection portions, caused by the conventional manual connection method which requires a worker to check the shapes of the connectors 510 one by one and then connect the connectors 510 to the plugs 3 in correction directions.

According to an embodiment of the disclosure, there is provided a connector automatic connecting system for a BSA inspection, in which connectors of an inspection apparatus are automatically connected to plugs provided in a battery system assembly.

Various embodiments of the present disclosure do not list all available combinations but are for describing a representative aspect of the present disclosure, and descriptions of various embodiments may be applied independently or may be applied through a combination of two or more.

A number of embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A automatic connecting system for a battery system assembly (BSA) inspection, comprising:
a vision unit configured to recognize a plurality of plugs provided in a battery system assembly;
a connector connecting unit configured to grip connectors, the connectors respectively matching the plurality of plugs among the connectors, move the gripped connectors to positions of those plugs, and then connect the connectors to the plugs;
one or more processors configured to execute instructions; and
a memory storing the instructions, wherein execution of the instructions configures the one or more processors to:
receive information about the plurality of plugs recognized by the vision unit; and
control the connector connecting unit to operate.

2. The automatic connecting system of claim 1, wherein the connector connecting unit comprises:
a first robot, the first robot comprising a first gripper configured to grip the connector; and
a second robot, the second robot comprising a second gripper configured to grip the connector, and
wherein a first degree of freedom of the first robot is different from a second degree of freedom of the second robot.

3. The automatic connecting system of claim 2, wherein the first robot is configured to implement 6 degrees of freedom motion, and
wherein the second robot is configured to implement 3 degrees of freedom motion.

4. The automatic connecting system of claim 2, wherein the first robot comprises a 6-axis multi-joint robot, and
wherein the second robot comprises an orthogonal robot.

5. The automatic connecting system of claim 2, wherein the first gripper and the second gripper each comprise one or more of a finger type that pressurizes at least two points of the connector, an adsorption type that adsorbs the connector, and a magnetic type that attaches the connector thereto with magnetism.

6. The automatic connecting system of claim 1, wherein the vision unit comprises a camera, and
wherein the vision unit is configured to face lateral and top surfaces of the battery system assembly to recognize the plurality of plugs.

7. The automatic connecting system of claim 6, wherein the vision unit further comprises a lighting unit configured to provide light.

8. The automatic connecting system of claim 1, wherein the memory includes plug data about the plurality of plugs and connector data about the connectors matching the plurality of plugs, and
wherein the one or more processors are further configured to:
receive information about the plurality of plugs recognized by the vision unit; and
compare the received information with the plug data and the connector data.

9. The automatic connecting system of claim 1, further comprising a frame unit in which the vision unit and the connector connecting unit are installed.

10. The automatic connecting system of claim 9, wherein the frame unit comprises:
a jig on which the battery system assembly is placed; and
a guide rail configured to guide the jig to move in a sliding motion.
